(19) United States
(12) Patent Application Publication
(10) Pub. No.: US 2024/0194580 A1
(43) Pub. Date: Jun. 13, 2024

(54) POWER SEMICONDUCTOR DEVICE WITH SOLDERABLE POWER PAD

(71) Applicant: Infineon Technologies AG, Neubiberg (DE)

(72) Inventors: Susanne Schulte, Dresden (DE); Scott David Wallace, Moritzburg (DE); Oliver Blank, Villach (AT)

(21) Appl. No.: 18/521,001

(22) Filed: Nov. 28, 2023

(30) Foreign Application Priority Data
Dec. 8, 2022 (DE) 102022132741.8

(51) Int. Cl. H01L 23/498; H01L 23/00

(52) U.S. Cl. CPC H01L 23/49838; H01L 23/49822; H01L 24/05; H01L 24/45; H01L 2224/05006; H01L 2224/05022; H01L 2224/05147; H01L 2224/45005; H01L 2224/4502; H01L 2924/01029; H01L 2924/014; H01L 2924/13055; H01L 2924/1306

(57) ABSTRACT

A power semiconductor device includes a semiconductor substrate. A signal routing structure is disposed above the semiconductor substrate. The signal routing structure comprises a specific metal. A solderable power pad forms a power terminal of the power semiconductor device. The solderable power pad comprises the specific metal. An electrically insulating dielectric passivation layer is disposed between the solderable power pad and the signal routing structure.

### TECHNICAL FIELD

This disclosure relates generally to the field of power semiconductor devices, and in particular to a power semiconductor device having a solderable power pad.

### BACKGROUND

Front-side Al-based metallizations of power chips are used for wire bonding. However, in many cases these metallizations are not or not readily suitable for solder connections. By replacing the conventional Al-based wire bonding power metallization on the front side of a power semiconductor chip with a solderable power metallization, the ohmic resistance and inductance of the chip-external electrical connection can be reduced, as low resistance/inductance connection techniques such as, e.g., clip or ribbon bonding become available. However, this change in interconnect technology has implications for layer integration of the back-end-of-line (BEOL) structure below the solderable power metallization in terms of moisture uptake, surface roughness, ion diffusion, and coefficient of thermal expansion (CTE) mismatch, for example.

### SUMMARY

According to an aspect of the disclosure, a power semiconductor device includes a semiconductor substrate. A signal routing structure is disposed above the semiconductor substrate. The signal routing structure comprises a specific metal. A solderable power pad forms a power terminal of the power semiconductor device. The solderable power pad comprises the specific metal. An electrically insulating dielectric passivation layer is disposed between the solderable power pad and the signal routing structure.

According to another aspect of the disclosure, a method of manufacturing a power semiconductor device comprises forming a signal routing structure over a semiconductor substrate, the signal routing structure comprising a specific metal; forming an electrically insulating dielectric passivation layer over the signal routing structure; and forming a solderable power pad representing a power terminal of the power semiconductor device over the dielectric passivation layer, the solderable power pad comprising the specific metal.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other and/or can be selectively omitted if not described to be necessarily required. Embodiments are depicted in the drawings and are exemplarily detailed in the description which follows.

FIG. 1 is a schematic cross-sectional representation of an example of a power semiconductor device including a metallization layer sequence above a semiconductor substrate, the metallization layer sequence including a signal routing structure and a solderable power pad of the exemplary power semiconductor device.

FIG. 2 is a flowchart of stages of an exemplary method of manufacturing a power semiconductor device having a solderable power pad.

FIGS. 3A-3D are schematic cross-sectional representations of stages of an exemplary method of manufacturing a power semiconductor device having a solderable power pad.

FIG. 4 illustrates an enlarged portion of FIG. 3D.

FIG. 5 is a schematic cross-sectional representation of an example of a power semiconductor device in which a signal routing structure includes a structure of a lower metallization and a structure of an upper metallization.

### DETAILED DESCRIPTION

It is to be understood that the features of the various exemplary embodiments and examples described herein may be combined with each other, unless specifically noted otherwise.

As used in this specification, the terms “deposited”, “covered by”, “connected” and/or “electrically connected” are not meant to mean that the elements or layers must directly be contacted together; intervening elements or layers may be provided between the “deposited”, “covered by”, “connected”, and/or “electrically connected” elements, respectively. However, in accordance with the disclosure, the above-mentioned terms may, optionally, also have the specific meaning that the elements or layers are directly contacted together, i.e. that no intervening elements or layers are provided between the “deposited”, “covered by”, “connected”, and/or “electrically connected” elements, respectively.

Further, the word “over” used with regard to a part, element or material layer formed or located or arranged “over” a surface may be used herein to mean that the part, element or material layer be located (e.g. placed, formed, arranged, deposited, etc.) “directly on”, e.g. in direct contact with, the implied surface. The word “over” used with regard to a part, element or material layer formed or located or arranged “over” a surface may either be used herein to mean that the part, element or material layer be located (e.g. placed, formed, arranged, deposited, etc.) “indirectly on” the implied surface with one or more additional parts, elements or layers being arranged between the implied surface and the part, element or material layer.

Referring to FIG. 1, an example of a power semiconductor device 100 includes a semiconductor substrate 110, a signal routing structure 140 disposed above the semiconductor substrate 110 and a solderable power pad 160 forming a power terminal of the power semiconductor device 100. An electrically insulating dielectric passivation layer 150 is disposed between the solderable power pad 160 and the signal routing structure 140.

Further, the power semiconductor device 100 may optionally include a dielectric power pad passivation layer 170 disposed over the dielectric passivation layer 150. The dielectric power pad passivation layer 170 may include an organic material (e.g. imide). More specifically, the dielectric power pad passivation layer 170 may include a layer stack comprising an organic dielectric layer 170_2 made of an organic material (e.g. imide) and, e.g., an inorganic dielectric layer 170_1.

The signal routing structure 140 is exemplified in FIG. 1 by a gate finger 140_1 and a gate runner 140_2. Other signal routing structures such as, e.g., a signal line (e.g., sense finger or sense line—not shown) may also be included in the signal routing structure 140 and may be disposed below the solderable power pad 160 (similar as the gate finger 140_1) or adjacent to the solderable power pad 160 (similar as the gate runner 140_2). The signal routing structure 140 is generated from or includes a lower metallization LM by using a structuring process, as will be described in more detail further below.

The solderable power pad 160 may be generated from an upper metallization UM by using another structuring process (see below). According to the disclosure, the lower metallization LM (and thus the signal routing structure 140, 1401, 1402) includes a specific metal, and the upper metallization UM (and thus the solderable power pad 160) also includes that specific metal.

This specific metal, which is used both for the lower metallization LM and the upper metallization UM, may, e.g., be Cu. Cu, for example, forms a solderable exposed surface 160A of the power pad 160.

Signal routing structures 140 such as, e.g., gate fingers 140_1 and gate runners 140_2 are used in power semiconductor devices for distributing the gate voltage across a transistor cell array to improve the switching speed of the device. Typically, gate runners 140_2 are used to provide a gate voltage supply along the boundaries of the transistor cell array, while gate fingers 140_1 traverse or intersect the transistor cell array.

Further, the lower metallization LM may provide for contact regions 140_3 which form the electrical contact between the front-end-of-line (FEOL) devices in the semiconductor substrate 110 and the power pad 160. The lower metallization LM may be in direct contact with the upper metallization UM (and thus the solderable power pad 160) at the contact regions 140_3 of the lower metallization LM, for example.

The dielectric passivation layer 150 used to protect the signal routing structure 140 from environmental attack and/or to electrically insulate parts of the signal routing structure (e.g. the gate fingers 140_1) from the solderable power pad 160 includes one or more inorganic dielectric materials that are free of any organic dielectric materials. For example, the dielectric passivation layer 150 may exclusively contain one or more inorganic dielectric materials. For example, the dielectric passivation layer 150 may include or be of silicon nitride and/or silicon oxide.

The signal routing structure 140, 1401, 140_2 may be made of a layer stack comprising an adhesion layer and/or barrier layer 130 and a layer 140 of the specific metal arranged over the adhesion layer and/or barrier layer 130. The layer of the specific metal 140 (e.g. a Cu layer) may be structured from the lower metallization LM. The lower metallization LM may, e.g., also include the layer 140 of the specific metal (e.g. Cu layer) or, more specifically, include or be a layer stack of an adhesion layer and/or barrier layer 130 and a layer 140 of the specific metal.

The power semiconductor device 100 may further include a bottom insulating dielectric layer 120 disposed between the semiconductor substrate 110 and the signal routing structure 140, 1401, 140_2. The dielectric passivation layer 150 together with the bottom insulating dielectric layer 120 may hermetically enclose an edge section of the signal routing structure 1401, 140_2 (see enlarged portion of FIG. 1).

The adhesion layer and/or barrier layer 130 may be an electrically conductive layer configured to increase adhesion of the layer of the specific metal 140 to the underlying bottom insulating dielectric layer 120. For example, the adhesion layer and/or barrier layer 130 includes or is a layer of TiW and/or Ti and/or W and/or TiN and/or Ta. TiW in particular provides good adhesion properties and good CTE matching in combination with a Cu layer 140.

The bottom insulating dielectric layer 120 may, e.g., include or be of SiN. The bottom insulating dielectric layer may provide a barrier against the migration of metal atoms (e.g. Cu atoms) and may therefore be relatively thick in comparison to the thickness of the adhesion layer and/or barrier layer 130, which only acts as an adhesion promoting layer.

By using the same specific metal for the signal solderable power pad 160 (upper metallization UM) and the routing structures 1401, 140_2 formed by the layer of the specific metal 140 (lower metallization LM) there is substantially no CTE mismatch occurring between these metallizations. In consequence, the passivation layer 150 disposed between the solderable power pad 160 and the signal routing structure (here, the gate finger 1401) as well as at the edges of the contact regions 1403 may, e.g., be free of organic dielectric materials.

In particular, the passivation layer 150 may be composed exclusively of inorganic dielectric materials, such as, e.g., silicon nitride and/or silicon oxide, with no risk of cracking. Such dielectrics do not absorb moisture and thus solve the problem of delamination of the signal routing structure, as known in the field of power devices, where conventionally different metals are used for the upper metallization UM and the lower metallization LM in combination with organic dielectric passivation layers, typically imides, for (often insufficient) passivation and CTE stress absorption between the two metallizations UM and LM.

The solderable power pad 160 (and thus the upper metallization UM) may have a thickness of 1 to 20 μm, in particular 4 to 11 μm. A substantial thickness is required in order to provide for the required mechanical stability during and after the soldering process.

The layer of the specific metal 140 (and thus, the lower metallization LM) may have a substantial smaller thickness of, e.g., 0.2 to 5 μm, in particular 0.5 to 3 μm. Compared to a conventional lower metallization LM, which is typically made of AlCu, the thickness of the layer of the specific metal 140 (e.g. Cu) may be reduced, since the specific metal (e.g. Cu) may have a higher electrical conductivity than AlCu. Hence, the thickness of the layer of the specific metal 140 may even be equal to or less than 3 or 2.5 or 2 or 1.5 μm, for example. A relatively small thickness of the layer of the specific metal 140 offers the following advantages:

First, the smaller the thickness of the layer of the specific metal 140, the finer the grains of this layer if, e.g., formed by plating. As a result, the upper metallization UM, and thus the solderable power pad 160, can be fabricated with an exposed surface 160A that is significantly smoother than would be the case if the layer of the specific metal 140 had a greater thickness. This avoids solder bonding problems known to occur on rough surfaces 160A of solderable power pads 160 due to entrapped contaminants.

In other words, if larger grains are not formed in the lower metallization LM due to the small thickness of the layer of the specific metal 140, the upper metallization UM can become finer grained because the underlying lower metallization LM is finer grained, resulting in a smooth exposed surface 160A that is optimum for bonding. In other examples, e.g. if the upper metallization UM is formed as a pure PVD metal, for example, the grain size and orientation may, however, depend on sputtering parameters.

Second, due to significantly thinner possible individual routing structures such as, e.g., gate or sense fingers 140_1 and/or gate runners 1402, either a better (lower) R_{DS(on)} can be achieved with the same chip size or the active area (e.g., the area of the array of transistor cells) and thus the chip size can be significantly reduced while maintaining the same R_{DS(on)}, resulting in a cost benefit.

Third, the reduced roughness and/or smaller grains of the layer of the specific metal 140 enables better ion- and moisture-tight passivation of the lateral edge section of the signal routing structures 140_1, 140_2. As shown in FIG. 1, edge passivation of the layer of the specific metal 140 may be provided by the bottom insulating dielectric layer 120 and the dielectric passivation layer 150.

Differently stated, the tightness of edge passivation of any structures of the lower metallization LM where the upper metallization UM and the lower metallization LM are close to each other (either overlapping or laterally spaced apart by a small distance) is improved by the above measures. This improves the reliability of the power semiconductor device 100, particularly in terms of resistance to moisture absorption and/or cracking of inorganic dielectric layers in regions between or close to the upper and lower metallizations UM and LM.

The dielectric passivation layer 150, which may be free of organic dielectric materials, may be present, for example, at least in regions between and/or in close lateral proximity to the metallizations UM, LM. The dielectric passivation layer 150 may, e.g., be the only insulating layer in these regions. The (optional) organic dielectric layer 170_2 does not significantly undercut the solderable power pad 160 at any location, for example. The meaning of “not significantly undercut” may optionally include (in addition to no undercut) a small undercut of, e.g., less than 2 or 1 μm which could, e.g., be created by wet etch of the adhesion layer and/or barrier layer 130.

In addition, the overall power semiconductor device 100 can be reduced in size as the lateral dimensions can be reduced due to the reduced thickness of the layer of the specific metal 140 and the reduced CTE mismatch (and thus the more space-efficient use of inorganic dielectric materials) in the BEOL integration of the power semiconductor device 100.

Basically, the semiconductor substrate 110 may, e.g., be a Si substrate, a Si-on-isolator (SOI) substrate, a GaN substrate, a SiC substrate, a GaAs substrate, or any other type of III-V or II-VI substrates, etc. The solderable power pad 160 may, e.g., be the source pad of a power transistor integrated in the power semiconductor device 100. For example, the power semiconductor device 100 may represent a discrete transistor device (including one transistor chip).

A variety of different FEOL integrations are available for a power semiconductor device 100 according to the disclosure. For example, the gate contacts 180 of the FEOL integrated transistor structure(s) may be made of polysilicon contacts, to which gate fingers 140_1 are electrically connected. In other examples the lower metallization LM may be used as such to form the gate contacts 180.

Some or all gate contacts 180 of a transistor cell array formed in the semiconductor substrate 110 may, e.g., be located underneath the solderable power pad 160, i.e. overlap with the solderable power pad 160 in a vertical projection. Gate contacts 180 are exemplified in FIG. 1 as trench gates. Reference numeral 185 refers to gate dielectrics isolating the gate contacts 180 from channel regions (not shown) of the power semiconductor device 100, for example.

The power semiconductor device 100 (e.g. a semiconductor chip) may, for example, be configured as an IGBT (Insulated Gate Bipolar Transistor), a FET (Field Effect Transistor), in particular a MOSFET (Metal Oxide Semiconductor FET) such as, e.g., a P-FET (P-channel FET), an N-FET (N-channel FET), an AFET (Array-FET), a JFET (Junction gate FET), a planar gate transistor, a field plate trench transistor, or a SJ (super junction) transistor.

The power semiconductor device 100 may, e.g., be a vertical device in which the main direction of the load current is in vertical direction to the chip plane. By way of example, a the solderable power pad 160 (e.g. source pad) and a gate pad (not shown) may be located on the front side of the device 100, while another power pad (e.g. drain power pad) of the power semiconductor device 100 may be provided by a backside metallization 190. In other examples, the power semiconductor device 100 may, e.g., be a horizontal or lateral device, in which the main direction of the load current is in a horizontal or lateral direction with the substrate plane. The disclosure is basically not limited to any particular FEOL integration, but a variety of different FEOL integrations (or device types) may benefit from this disclosure.

Referring to vertical power semiconductor device 100 as exemplified in FIG. 1, the backside metallization 190 may, e.g., include a Ti/NiV/Ag layer stack. For example, if Ag is used for the backside metallization 190, Ag dendrite growth at the front side is a known problem in the art. Such Ag dendrite growth (also known as Ag migration) is (also) substantially prevented by a dielectric passivation layer 150 free of organic dielectrics.

More generally stated, also the edge of the power semiconductor device 100 (e.g. chip) is effectively sealed against environmental attack by the concept of using upper and lower metallization layers UM, LM comprising the same specific metal and an inorganic dielectric passivation layer 150.

In conclusion, the entire device 100 may be sized down since lateral dimensions can be reduced as a result of a smaller thickness of the layer of the specific metal 140 and the lower CTE mismatch (and thus the more space-efficient usage of inorganic dielectric materials) in the BEOL integration of the power semiconductor device 100. Further, as mentioned before, Cu as an option for the upper metallization layer UM (and hence for the solderable power pad 160) will have significant reduced roughness due to the underlying thin Cu layer 140 (lower metallization LM) with small grains. As apparent from FIG. 1, the power semiconductor device 100 may provide a direct interface between the upper metallization UM and the lower metallization LM at, for example, the contact regions 140_3 for the solderable power pad 160.

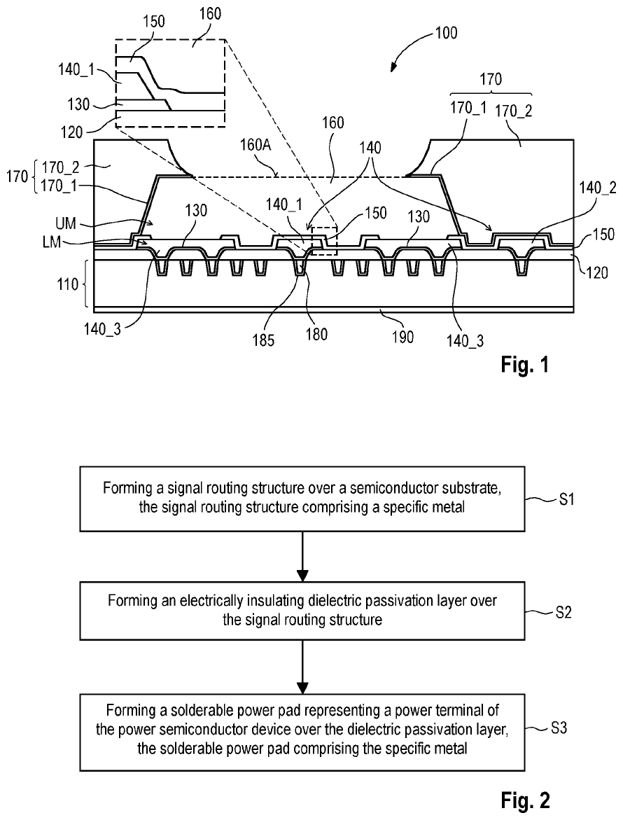

Referring to FIG. 2, exemplary stages of manufacturing a power semiconductor device are described. At S1 a signal routing structure is formed over a semiconductor substrate, wherein the signal routing structure comprises a specific metal.

At S2 an electrically insulating dielectric passivation layer is formed over the signal routing structure. For example, the electrically insulating dielectric passivation layer may not include an organic dielectric material, such as an imide.

At S3 a solderable power pad representing a power terminal of the power semiconductor device is formed over the dielectric passivation layer. The solderable power pad includes the specific metal or, in particular, is predominantly (e.g., with the exception of thin lower and/or upper liners) or exclusively made of the specific metal.

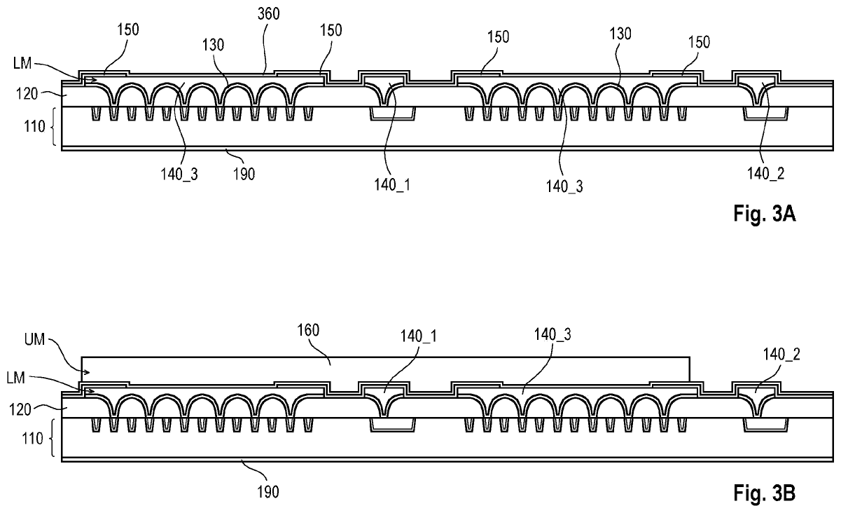

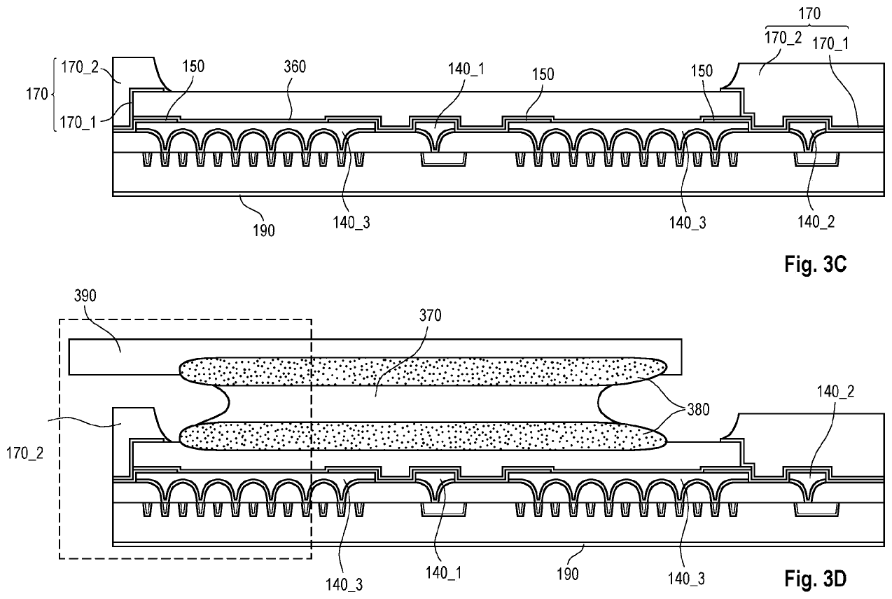

FIGS. 3A-3D illustrate stages of an exemplary method of manufacturing an exemplary power semiconductor device having a solderable power pad 160. Processes and/or features described for this example may be omitted unless explicitly stated as essential processes or features. Further, specific processes of FIGS. 3A-3D may be combined with the method of FIG. 2 in arbitrary intermediate generalizations.

Referring to FIG. 3A, a semiconductor substrate 110 in the form of a wafer is provided. The wafer was previously subjected to FEOL processing.

A bottom insulating dielectric layer 120 of, e.g., SiN and/or undoped silicon glass (USG) has been deposited by, e.g., using CVD over the semiconductor substrate 110 and structured in accordance with the integrated FEOL devices previously formed in the semiconductor substrate 110.

Optionally, the adhesion layer and/or barrier layer 130 and a Cu seed layer (not shown) are applied over the bottom insulating dielectric layer 120. The adhesion layer and/or barrier layer 130 and the Cu seed layer (not shown) may be structured in conformity with the structures (in particular signal routing structures 140_1, 1402 and contact region 140_3) of the layer of the specific metal 140 to be formed over the (structured) bottom insulating dielectric layer 120.

For example, if a TiW/Cu stack is used for the adhesion layer and/or barrier layer 130 and the layer of the specific metal 140, this layer stack may be structured by Cu chemical wet etching and TiW plasma etching, for example. Another possibility is to use chemical wet etching both for the layer of the specific metal 140 (e.g. Cu) and the adhesion layer and/or barrier layer (e.g. TiW) followed by a Cu pullback with a resist mask on top, which is removed after the Cu pullback.

Still referring to FIG. 3A, the dielectric passivation layer 150 is then formed over the lower metallization LM and structured to form openings for the contact regions 140_3. The dielectric passivation layer 150 is not removed over the signal routing structures (e.g., gate fingers 140_1 and/or gate runners 1402) so as to provide the electrical insulation between signal routing structures 140_1, 140_2 and the upper metallization UM to be applied later.

Then, a (second) seed layer 360 (e.g., Cu seed layer) may be deposited over the structured lower metallization LM.

FIG. 3B illustrates a specific example of forming the solderable power pad 160 over the structured lower metallization LM. The solderable power pad 160 includes the specific metal (e.g. Cu) of the layer 140 of the lower metallization LM. The process of forming the solderable power pad 160 may be carried out as follows:

A first possibility is to form the solderable power pad 160 by PVD followed by Cu chemical wet etching for patterning.

A second possibility is to provide a seed layer (e.g. Cu seed) by PVD followed either by (a) galvanic plating of the specific metal (e.g., Electro Chemical Copper Deposition (ECD)) within a resist pattern followed by seed layer etch or (b) galvanic plating of the specific metal (e.g., Electro Chemical Copper Deposition (ECD)) followed by wet/plasma etch structuring of the entire metal stack.

A third possibility is to use a Cu Damascene process to form the solderable power pads 160.

In FIGS. 3A and 3B the solderable power pad 160 has, for example, been generated by option (a) of the second possibility (PVD seed—ECD in resist pattern (not shown)—seed etching, which has not yet been done in FIG. 3B).

Subsequently, e.g. after seed layer 360 etching, the front side of the power semiconductor device 100 may be passivated, for example. To that end, the dielectric power pad passivation layer 170 may be generated.

For example, the dielectric power pad passivation layer 170 may be formed as a layer stack comprising the inorganic dielectric layer 170_1 and the organic dielectric layer 170_2. The inorganic dielectric layer 170_1 may, e.g., comprise or be of SiN and/or SiOx and/or SiON or any other hard passivation layer. The organic dielectric layer 170_2 may be used as a buffer coating including, e.g., an imide and/or Polybenzoxazole (PBO) and/or epoxy and/or similar organic dielectrics.

As shown in FIG. 1, the inorganic dielectric layer 1701 may cover a signal routing structure such as, e.g., the gate runner 140_2. On the other hand, the inorganic dielectric layer 170_1 may not cover signal routing structures such as, e.g., the gate finger 140_1 which are overlaid by the solderable power pad 106. Further, as also shown in FIG. 1, the inorganic dielectric layer 170_1 (as well as the organic dielectric layer 1702) does, e.g., not reach in any region between the lower metallization LM and the upper metallization UM, for example between the contact region 140_3 of the layer of the specific metal 140 and the solderable power pad 160.

The dielectric power pad passivation layer 170 may, e.g., cover sidewalls and/or the upper edge region of the solderable power pad 160, e.g., as shown in FIG. 3C. The dielectric power pad passivation layer 170 can provide ion- and moisture-tight protection for the solderable power pad 160.

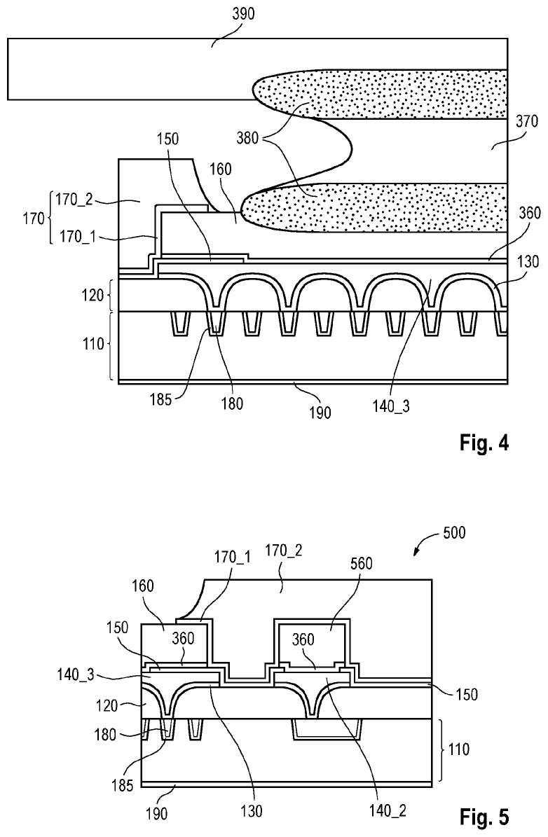

FIG. 3D illustrates the power semiconductor device 100 after being soldered to a power conductor 390. The power conductor 390 may be a package-internal conductor of the power semiconductor device 100 such as, e.g., a clip or ribbon. In other examples, the power conductor 390 may be any other conductor or conducting pad (e.g. metal pad on a carrier or on an application board) to which the power semiconductor device 100 is to be soldered. The power conductor 390 may, e.g., be of the specific metal, e.g. Cu. An enlarged portion of FIG. 3D is illustrated in FIG. 4, for example.

The solder connection may, e.g., be a soft solder connection or a diffusion solder connection, as shown in FIG. 3D, for example. In a diffusion solder connection, intermetallic phases 380 between the metal of the power conductor 390 and/or the metal of the solderable power pad 160 are formed.

For example, the solder may, e.g., be a PbSn solder or any other solder known in the art. The intermetallic phases 380 may, e.g., be CuSn intermetallic phases comprising, e.g., Cu3Sn and/or Cu6Sn5, for example.

FIG. 5 illustrates a partial view of an example of a power semiconductor device 500. The power semiconductor device 500 may be identical with power semiconductor device 100 except that the signal routing structure as exemplified by the gate runner 140_2 (or any other part which is not located below or overlapping with the solderable power pad 160) further includes an additional routing structure 560 of the upper metallization UM. In this case, the dielectric passivation layer 150 is removed in this region before the seed layer 360 (e.g., Cu seed layer) is deposited over the structured lower metallization LM (e.g. gate runner 140_2). Thus, similar as for the contact regions 140_3 (see FIG. 1), the lower metallization LM may be in direct contact with the upper metallization UM at the signal routing structure 1402, 560 of FIG. 5.

The additional routing structure 560 of the upper metallization UM increases the routing capability of the signal routing structure 140_2, 560 by decreasing the electrical resistance thereof. The signal routing structure 1402, 560 may be covered by the inorganic dielectric layer 170_1 and the organic dielectric layer 170_2. In some examples, only the inorganic dielectric layer 170_1 and the organic dielectric layer 170_2 are used to cover the signal routing structure 140_2, 560.

For all other features of power semiconductor device 500, reference is made to the above description to avoid reiteration.

The following examples pertain to further aspects of the disclosure:

Example 1 is a power semiconductor device, comprising: a semiconductor substrate; a signal routing structure disposed above the semiconductor substrate, the signal routing structure comprising a specific metal; a solderable power pad forming a power terminal of the power semiconductor device, the solderable power pad comprising the specific metal; and an electrically insulating dielectric passivation layer disposed between the solderable power pad and the signal routing structure.

In Example 2, the subject matter of Example 1 can optionally include wherein the specific metal is Cu.

In Example 3, the subject matter of Example 1 or 2 can optionally include wherein a cross section of the signal routing structure is partly or fully overlaid by the solderable power pad.

In Example 4, the subject matter of any preceding Example can optionally include wherein the signal routing structure is a gate or sense signal connection structure, in particular a gate finger or a gate runner or a sense signal line.

In Example 5, the subject matter of any preceding Example can optionally include wherein the dielectric passivation layer is free of organic dielectric materials.

In Example 6, the subject matter of any preceding Example can optionally include wherein the dielectric passivation layer comprises silicon nitride and/or silicon oxide and/or silicon oxi-nitride.

In Example 7, the subject matter of any preceding Example can optionally include wherein the signal routing structure is made of a layer stack comprising an adhesion layer and/or barrier layer and a layer of the specific metal arranged over the adhesion layer.

In Example 8, the subject matter of Example 7 can optionally include wherein the adhesion layer and/or barrier layer comprises a layer of TiW and/or Ti and/or W and/or TiN and/or Ta.

In Example 9, the subject matter of Example 7 or 8 can optionally include wherein the layer of the specific metal has a thickness of 0.2 to 5 μm, in particular 0.5 to 3 μm.

In Example 10, the subject matter of any preceding Example can optionally further include a bottom insulating dielectric layer disposed between the semiconductor substrate and the signal routing structure, wherein the dielectric passivation layer together with the bottom insulating dielectric layer hermetically enclose an edge section of the signal routing structure.

In Example 11, the subject matter of any preceding Example can optionally include wherein the solderable power pad has a thickness of 1 to 20 μm, in particular 4 to 11 μm.

In Example 12, the subject matter of any preceding Example can optionally further include an organic dielectric layer disposed over the dielectric passivation layer, wherein the organic dielectric layer does not significantly undercut the solderable power pad.

In Example 13, the subject matter of any preceding Example can optionally include wherein the power semiconductor device is a vertical device or a lateral device.

In Example 14, the subject matter of any preceding Example can optionally include wherein the power semiconductor device is an IGBT, MOSFET, JFET, P-FET, N-FET, AFET, planar gate transistor, field plate trench transistor, or super junction transistor.

Example 15 is a method of manufacturing a power semiconductor device, the method comprising: forming a signal routing structure over a semiconductor substrate, the signal routing structure comprising a specific metal; forming an electrically insulating dielectric passivation layer over the signal routing structure; and forming a solderable power pad representing a power terminal of the power semiconductor device over the dielectric passivation layer, the solderable power pad comprising the specific metal.

In Example 16, the subject matter of Example 15 can optionally include wherein forming the signal routing structure comprises deposition a layer of the specific metal over the semiconductor substrate; and structuring the layer of the specific metal by chemical wet etching to form the signal routing structure.

In Example 17, the subject matter of Example 15 or 16 can optionally include wherein forming the dielectric passivation layer comprises depositing a passivation layer that comprises an inorganic dielectric material and is free of organic dielectric materials over the signal routing structure.

In Example 18, the subject matter of any of Examples 15 to 17 can optionally include wherein forming the solderable power pad comprises depositing a layer of the specific metal over the dielectric passivation layer.

In Example 19, the subject matter of Example 18 can optionally include wherein depositing the layer of the specific metal over the dielectric passivation layer comprises physical vapor deposition of the specific metal followed by chemical wet etching of the specific metal, or physical vapor deposition of a seed layer followed either by galvanic plating of the specific metal and etching of the layer of the specific metal and the seed layer or by galvanic plating of the specific metal within a resist pattern and seed layer etching, or electroless plating, or a Cu Damascene process.

In Example 20, the subject matter of any of Examples 15 to 19 can optionally include wherein forming the dielectric passivation layer over the signal routing structure comprises hermetically enclosing an edge section of the signal routing structure.

In Example 21, the subject matter of any of Examples 15 to 20 can optionally include wherein forming the solderable power pad comprises burying at least a cross section of the signal routing structure beneath the solderable power pad.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A power semiconductor device, comprising:
a semiconductor substrate;
a signal routing structure disposed above the semiconductor substrate, the signal routing structure comprising a specific metal;
a solderable power pad forming a power terminal of the power semiconductor device, the solderable power pad comprising the specific metal; and
an electrically insulating dielectric passivation layer disposed between the solderable power pad and the signal routing structure.

2. The power semiconductor device of claim 1, wherein the specific metal is Cu.

3. The power semiconductor device of claim 1, wherein a cross section of the signal routing structure is partly or fully overlaid by the solderable power pad.

4. The power semiconductor device of claim 1, wherein the signal routing structure is a gate or sense signal connection structure.

5. The power semiconductor device of claim 1, wherein the dielectric passivation layer is free of organic dielectric materials.

6. The power semiconductor device of claim 1, wherein the dielectric passivation layer comprises silicon nitride and/or silicon oxide and/or silicon oxi-nitride.

7. The power semiconductor device of claim 1, wherein the signal routing structure is made of a layer stack comprising an adhesion layer and/or barrier layer and a layer of the specific metal arranged over the adhesion layer and/or barrier layer.

8. The power semiconductor device of claim 7, wherein the adhesion layer and/or barrier layer comprises a layer of TiW and/or Ti and/or W and/or TiN and/or Ta.

9. The power semiconductor device of claim 7, wherein the layer of the specific metal has a thickness of 0.2 to 5 μm.

10. The power semiconductor device of claim 1, further comprising:
a bottom insulating dielectric layer disposed between the semiconductor substrate and the signal routing structure,
wherein the dielectric passivation layer together with the bottom insulating dielectric layer hermetically enclose an edge section of the signal routing structure.

11. The power semiconductor device of claim 1, wherein the solderable power pad has a thickness of 1 to 20 μm.

12. The power semiconductor device of claim 1, further comprising:
an organic dielectric layer disposed over the dielectric passivation layer,
wherein the organic dielectric layer does not significantly undercut the solderable power pad.

13. The power semiconductor device of claim 1, wherein the power semiconductor device is a vertical device or a lateral device.

14. The power semiconductor device of claim 1, wherein the power semiconductor device is an IGBT, MOSFET, JFET, P-FET, N-FET, AFET, planar gate transistor, field plate trench transistor, or super junction transistor.

15. A method of manufacturing a power semiconductor device, the method comprising:
forming a signal routing structure over a semiconductor substrate, the signal routing structure comprising a specific metal;
forming an electrically insulating dielectric passivation layer over the signal routing structure; and
forming a solderable power pad representing a power terminal of the power semiconductor device over the dielectric passivation layer, the solderable power pad comprising the specific metal.

16. The method of claim 15, wherein forming the signal routing structure comprises:
depositing a layer of the specific metal over the semiconductor substrate; and
structuring the layer of the specific metal by chemical wet etching to form the signal routing structure.

17. The method of claim 15, wherein forming the dielectric passivation layer comprises:
depositing, over the signal routing structure, a passivation layer that comprises an inorganic dielectric material and is free of organic dielectric materials.

18. The method of claim 15, wherein forming the solderable power pad comprises:
depositing a layer of the specific metal over the dielectric passivation layer.

19. The method of claim 18, wherein depositing the layer of the specific metal over the dielectric passivation layer comprises:
physical vapor depositing of the specific metal followed by chemical wet etching of the specific metal, or
physical vapor deposition of a seed layer followed either by galvanic plating of the specific metal and etching of the layer of the specific metal and the seed layer or by galvanic plating of the specific metal within a resist pattern and seed layer etching, or
electroless plating, or
a copper damascene process.

20. The method of claim 15, wherein forming the dielectric passivation layer over the signal routing structure comprises hermetically enclosing an edge section of the signal routing structure.

21. The method of claim 15, wherein forming the solderable power pad comprises burying at least a cross section of the signal routing structure beneath the solderable power pad.
